(19) United States
(12) Patent Application Publication
(10) Pub. No.: US 2012/0002355 A1
(43) Pub. Date: Jan. 5, 2012

(54) Vehicle-Mounted Electronic Product with Magnetic Connector and its Mounting Bracket

(76) Inventor: Kuo Hsiung Chen, Kowloon (CN)

(21) Appl. No.: 13/007,823

(22) Filed: Jan. 17, 2011

(30) Foreign Application Priority Data
Jul. 1, 2010 (CN) 201020253247.1
Dec. 10, 2010 (EP) 10252096.2

(51) Int. Cl. H05K 7/00

(52) U.S. Cl. 361/679.01

(57) ABSTRACT

A vehicle-mounted electronic product comprises an electronic product body. The electronic product body is equipped with a first port of the magnetic connector. The first port comprises a primary body shell, magnets mounted on the primary body shell, and several first signal pins. The mounting bracket comprises a bracket body for fixing the vehicle-mounted electronic product in place. A second port of the magnetic connector is placed on said bracket body. The second port comprises a secondary body shell, magnets mounted on the secondary body shell, and several second signal pins. The second port and the first port of the magnetic connector are fit together by magnets. The vehicle-mounted electronic product and its mounting bracket utilize the magnetic force from the connector to fit the first port and the second port together in a floatable condition, enabling a more reliable and steadier signal transmission.

### BACKGROUND

This invention relates to a portable vehicle-mounted electronic product and its mounting bracket, particularly a vehicle-mounted electronic product with magnetic connector and its mounting bracket.

It is getting more popular for vehicle users to install varieties of electronic products such as DVD players and multimedia players in their own cars. Usually these electronic products are mounted on the seatbacks of the front seats to enable the rear passengers to enjoy entertainment while the cars are moving.

For instance, a Chinese Utility Model No. CN 2777708Y as approved and published on 3 May 2006 discloses a mounting bracket for portable visual electronic product. After installation of the mounting bracket onto a car seat (headrest), an electronic product could be secured to the fixing base on the other end of the mounting bracket. Another Chinese Utility Model No. CN 2816989Y as approved and published on 13 September 2006 discloses a fixing base for a portable visual electronic product which could fix a portable visual electronic product to a different location in an automobile vehicle such as headrest support rod or to sun visor.

Nowadays, the connection between mounting brackets and electronic products (such as car DVD player, iPad, iPhone) is usually through connectors, and the power, audio, video and other signals are transmitted through the corresponding ports of the connectors. However, as the connector ports are usually fixed and immovable, they often lead to problems like unstable signal transmission and susceptibility to damages in service. For example, the pictures and sounds on the DVD player carried by a moving car are often affected by bumps on the road. In some cases the DVD player may even come to a halt or restart by itself. This will not only affect the performance of the DVD player but also increase the chances of damage. Therefore most car DVD players have become something like ornaments and caused inconveniences during use. Given the above situation, it is very important to find a solution to the connector stability problem.

### SUMMARY

A vehicle-mounted electronic product with magnetic connector and its mounting bracket enable a more stable electric signal transmission between the mounting bracket and the vehicle-mounted electronic product.

The vehicle-mounted electronic product is provided with a magnetic connector. The vehicle-mounted electronic product has an electronic product body. The said electronic product body is equipped with a first port of the magnetic connector. The first port comprises a primary body shell, magnets mounted on the primary body shell, and several first signal pins.

In some embodiments, the first signal pins may have a built-in spring, and the pin heads reach out under the effect of built-in spring and stick out of the pin holes of the primary body shell. The tail ends may be connected to the signal wires installed inside the product and used to transmit electric signals. The length of each of the first signal pin heads reaching out from the primary body shell may be different, thus enabling receipt of an electric signal from the second port of the magnetic connector according to a sequence determined by the different lengths of the pin heads.

There may be a slot on the back of the electronic product body. The slot may be for receiving a connecting block of a mounting bracket (described below). The first port is preferably installed within the slot.

For use in conjunction with said vehicle-mounted electronic product, a mounting bracket has a magnetic connector. The mounting bracket comprises a bracket body for fixing the vehicle-mounted electronic product. A second port of the magnetic connector is provided on said bracket body. The second port comprises a secondary body shell, magnets mounted on the secondary body shell, and several second signal pins. The second port and the first port of the magnetic connector can fit together and be held together by the magnets.

In some embodiments, the second signal pins may be fixed to the secondary body shell with their pin heads pointing at the corresponding first signal pins of the first port. Their tail ends may be connected to the signal wires installed inside the product and are used to transmit electric signals. When the first signal pins have electrical contact with the second signal pins, the elastic force on the first signal pins and the pressure on the second signal pins constitute a couple for forces.

The bracket body preferably comprises a transversal fixed rod installed between the car headrest and seatback, a longitudinal expansion rod connected to the middle of the transversal fixed rod, and a mounting base connected to one end of the longitudinal expansion rod. A connecting block may be placed on the mounting base. The second port may be mounted on the connecting block. A tact switch capable of triggering the connecting block to bounce up may also be placed on the mounting base.

The vehicle-mounted electronic product and mounting bracket including the magnetic connector is superior to the existing technologies in the following respects: (1) The vehicle-mounted electronic product and the mounting bracket are fit together by the magnetic force between the first port and the second port. The second port is floatable and can follow the movements of the first port in order to ensure close contact between the first signal pins and the second signal pins, prevent relative slip, improve the stability of signal transmission, and free the device of the impact of external bumps. (2) The magnetic connector has a simple and practical structure which applies to all kinds of port connection that need data transmission or have other connection requirements. (3) The product achieves good contact between the ports without any pressure applied. The magnets in the connector serve as an orienting mechanism which makes the connector easier and more convenient to use.

### BRIEF DESCRIPTION OF THE DRAWINGS

A preferred embodiment of the present invention will now be described by way of example only, with reference to the accompanying drawings, in which:

FIG. 1 shows a structure view of a mounting bracket;

FIG. 2 shows a side structure view of the mounting bracket shown in FIG. 1;

FIG. 3 shows the separated structure of the mounting bracket shown in FIGS. 1 and 2;

FIG. 4 shows the enlarged diagram of the second port of the mounting bracket shown in FIGS. 1-3;

FIG. 5 shows the enlarged diagram of the first port of an embodiment of a vehicle-mounted electronic product configured to couple with the mounting bracket shown in FIGS. 1-4;

FIG. 6 shows an exploded view of the structure of the magnetic connector of the embodiment shown in FIGS. 1-5;

FIG. 7 shows the structure of the magnetic connector of the embodiment shown in FIGS. 1-6;

FIG. 8 shows the assembly process of the vehicle-mounted electronic product and the mounting bracket of the embodiment shown in FIGS. 1-7;

FIG. 9 shows the structure of the vehicle-mounted electronic product and the mounting bracket of the embodiment shown in FIGS. 1-7 after the assembly is completed.

### DETAILED DESCRIPTION

The present invention will be exemplified and illustrated in more detail below using an embodiment of a car DVD player as an example. Of course, other implementations are possible and are within the scope of the present invention.

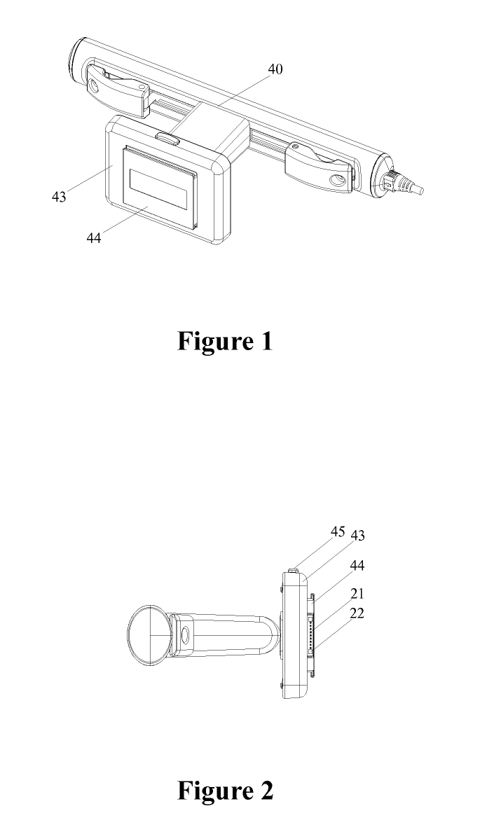

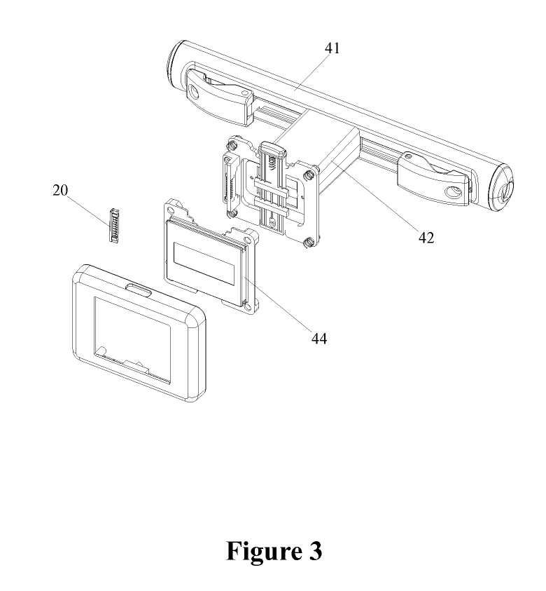

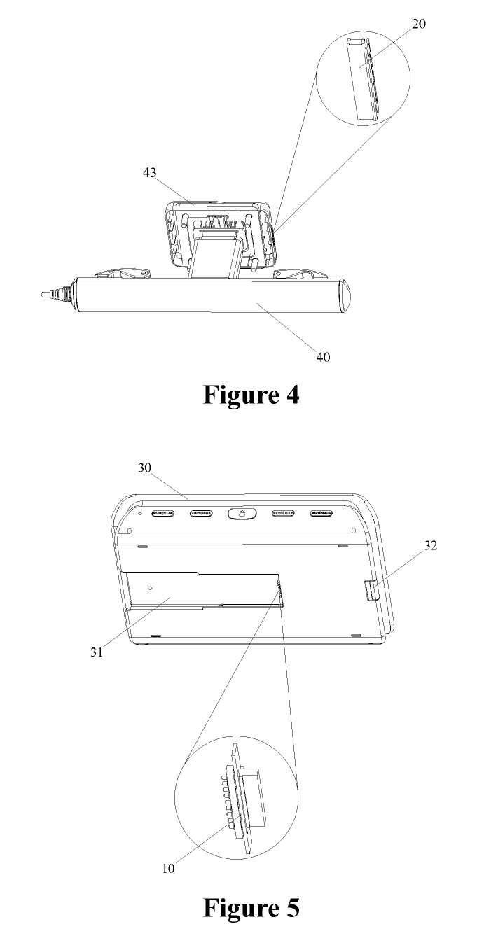

The present invention relates a vehicle-mounted electronic product with magnetic connector and its mounting bracket. The said vehicle-mounted electronic product and its mounting bracket are connected through a magnetic connector. As shown in FIGS. 1 to 4, the mounting bracket of said vehicle-mounted electronic product comprises a bracket body 40. The bracket body comprises a transversal fixed rod 41 installed between the headrest and backrest of the car seat, a longitudinal expansion rod 42 connected to the middle of the transversal fixed rod, and a mounting base 43 connected to one end of the longitudinal expansion rod. A connecting block 44 is placed on the mounting base. A second port 20 of the magnetic connector is mounted on the connecting block (as shown in FIG. 4). In addition a tact switch 45 switch capable of triggering the connecting block 44 to bounce up is also placed on the mounting base 43. As shown in FIG. 5, said vehicle-mounted electronic product (e.g. a car DVD player) comprises the electronic product body 30. A slot 31 is placed on the back of the electronic product body. The first port 10 of the magnetic connector is placed inside the slot 31. In addition, a release switch 32 is also placed on one side of the electronic product body 30. When this release switch is pressed, the bracket body 40 can be unlocked from the electronic product body 30.

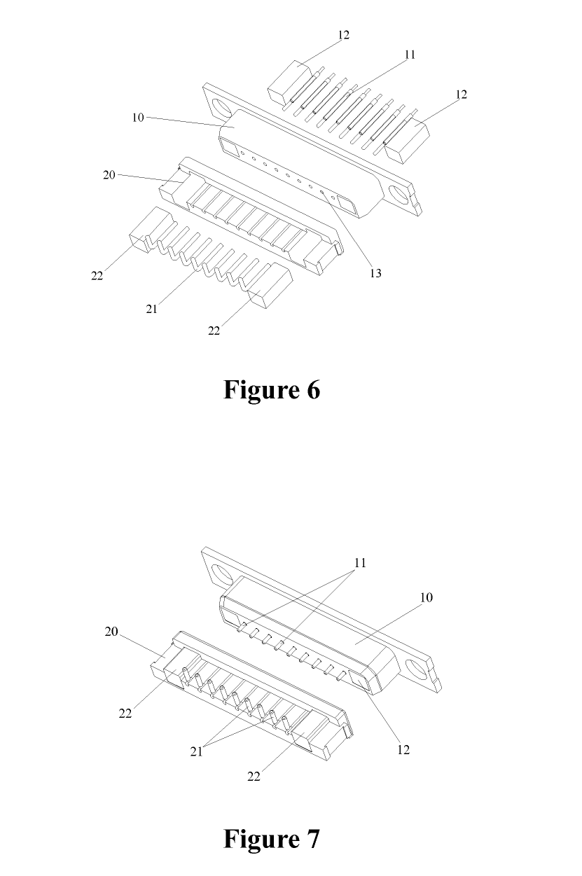

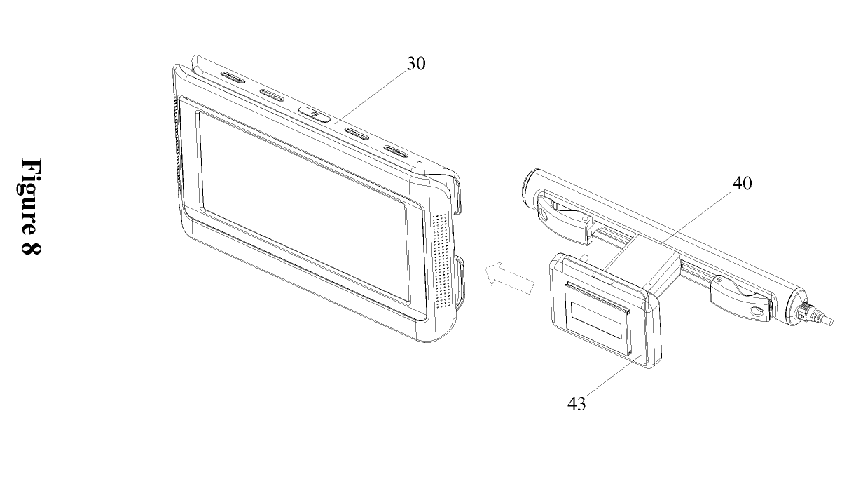

As shown in FIG. 6 and FIG. 7, the magnetic connector of this invention comprises a first port (commonly known as male port) and a second port (commonly known as female port) wherein: said first port comprises a primary body shell 10 which is fixed to the corresponding device (e.g. a car DVD player) and further comprises two or more magnets 12 and several first signal pins 11 (also known as male signal pins) mounted on the primary body shell 10. The first signal pins are installed on the primary body shell 10 and each of them has a head and a tail. The heads reach out under the effect of a built-in spring (not shown on the diagram) and stick out of the pin holes 13 in the primary body shell. They are used for connection with second signal pins 21 of the second port. Their tail ends are connected to the signal wires installed inside the device and used to transmit power, audio, video, testing, control, and other electric signals. The distance by which the heads of the first signal pins 11 stick out varies with their functions, so that different electric signals are accessed according to a sequence determined by the different lengths of their heads when they are connected to the second signal pins. The second port comprises a secondary body shell 20 and two or more magnets 22 and several second signal pins 21 (also known as female signal pins) fixed onto the secondary body shell. The heads of the second signal pins 21 point at the corresponding first signal pins 11. Their L-shaped tails are connected to the signal wires installed inside the device and are used to transmit power, audio, video, testing, control, and other electric signals. The second port is installed on a corresponding device (e.g. mounting bracket of the car DVD player) with a motion clearance allowed between the port and the mounting position of the device. Furthermore, magnets 12 and 22 of the first port and the second port are of different polarities so that they can be drawn to each other.

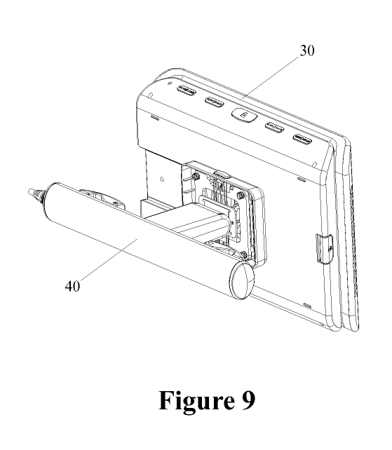

As indicated in FIG. 8, the tact switch 45 on the mounting bracket is pressed so that the connecting block 44 bounces up onto the mounting base 43 before use. Then the connecting block 44 slides into the slot 31 on the back of the vehicle-mounted electronic product so that the first port and the second port of the magnetic connector are fit together under the effect of the opposite poles of magnets 12 and 22. The second signal pins 21 and the first signal pins 11 are firmly pressed together. The elastic force on the first signal pins 11 and the pressure on the second signal pins constitute a couple of forces which ensures good contact between signal pins. As the second port has certain floatability and can move with the first port, the force between the first signal pins and the second signal pins is mainly in the vertical direction. Therefore they do not have relative sliding motion and as a result, the connection is more reliable and stable and the signal transmission is steadier and free of the impact of external bumps. FIG. 9 is a schematic view of the overall structure of an assembled vehicle-mounted electronic product (DVD player) and its mounting bracket. 27

This invention could also apply on a variety of data and signal transmission ports, such as those ports for DVD, iPad, iPhone. Through the floatable port, a more reliable and steadier signal transmission could be achieved.

1. A vehicle-mounted electronic product comprising an electronic product body having a first port of a magnetic connector, wherein the first port of the magnetic connector comprises a primary body shell having magnets and a plurality of first signal pins installed in the primary body shell.

2. The vehicle-mounted electronic product as claimed in claim 1, wherein the first signal pins have a head end and a tail end and signal wires are installed in the electronic product, and further comprising one or more springs provided for causing the pin head of the first signal pins to stick out of pin holes provided in the primary body shell, wherein the tail ends of the first signal pins are connected to the signal wires installed inside the electronic product and are used to transmit electric signals.

3. The vehicle-mounted electronic product as claimed in claim 2, wherein the first port is configured such that the distance by which the different heads of said first signal pins stick out of the primary body shell varies so that different electric signals are accessed according to a sequence determined by the different lengths of their heads when they are connected, in use, to second signal pins in a second port of a the magnetic connector.

4. The vehicle-mounted electronic product as claimed in claims 1, further comprising a slot arranged in the electronic product body and wherein said first port is arranged in the slot.

5. The vehicle-mounted electronic product as claimed in claim 1, wherein the vehicle mounted electronic product is configured to be fixable to a mounting bracket such that the first port of the magnetic connector connects electrically in use to the second port of the magnetic connector provided in the mounting bracket, and such that the second port and first port are held together in use by magnets.

6. A mounting bracket comprising a bracket body for fixing the vehicle-mounted electronic product of claim 1 in place, the bracket body having a second port of a magnetic connector, wherein the second port comprises a secondary body shell having magnets and several second signal pins installed in the secondary body shell, wherein the second port is configured such that the second port can fit together with the first port of the magnetic connector, and such that the second port and first port are held together in use by magnets.

7. The mounting bracket as claimed in claim 6, wherein said second signal pins are fixed to the secondary body shell such that their pin heads point, in use, at the corresponding first signal pins of the first port, and wherein the tail ends of the second signal pins are connected to the signal wires installed inside the mounting bracket and are used to transmit electric signals.

8. The mounting bracket as claimed in claim 7, wherein the magnetic connector ports are configured such that when the first signal pins have electrical contact with the second signal pins, an elastic spring force exerted on the second signal pins by the first signal pins provides a coupling between the respective first signal pins and second signal pins.

9. The vehicle mount electronic product and mounting bracket as claimed in claim 5, wherein the bracket body comprises: a transversal fixed rod for installation between a headrest and a backrest of a car seat; a longitudinal expansion rod connected to the middle of the transversal fixed rod; and a mounting base connected to one end of the longitudinal expansion rod; wherein a connecting block is provided on said mounting base and said second port is mounted on the connecting block.

10. The vehicle mount electronic product and mounting bracket as claimed in claim 9, further comprising a tact switch provided on said mounting base and arranged to cause the connecting block to protrude from the mounting base.

11. A vehicle-mounted electronic product and the mounting bracket of claim 6, wherein the electronic product is capable of being fixed by the mounting bracket such that the first port of the magnetic connector connects electrically in use to the second port of the magnetic connector provided in the mounting bracket, and such that the second port and first port are held together in use by magnets.

12. The vehicle-mounted electronic product and mounting bracket of claim 11 fixed together, wherein the mounting bracket is fixed between a headrest and a backrest of a car seat.

13. The vehicle-mounted electronic product as claimed in claim 2, further comprising a slot arranged in the electronic product body and wherein said first port is arranged in the slot.

14. The vehicle-mounted electronic product as claimed in claims 3, further comprising a slot arranged in the electronic product body and wherein said first port is arranged in the slot.

15. The vehicle-mounted electronic product as claimed in claim 2, wherein the vehicle mounted electronic product is configured to be fixable to a mounting bracket such that the first port of the magnetic connector connects electrically in use to the second port of the magnetic connector provided in the mounting bracket, and such that the second port and first port are held together in use by magnets.

16. The vehicle-mounted electronic product as claimed in claim 3, wherein the vehicle mounted electronic product is configured to be fixable to a mounting bracket such that the first port of the magnetic connector connects electrically in use to the second port of the magnetic connector provided in the mounting bracket, and such that the second port and first port are held together in use by magnets.

17. The vehicle-mounted electronic product as claimed in claim 4, wherein the vehicle mounted electronic product is configured to be fixable to a mounting bracket such that the first port of the magnetic connector connects electrically in use to the second port of the magnetic connector provided in the mounting bracket, and such that the second port and first port are held together in use by magnets.

18. A mounting bracket comprising a bracket body for fixing the vehicle-mounted electronic product of claim 2 in place, the bracket body having a second port of a magnetic connector, wherein the second port comprises a secondary body shell having magnets and several second signal pins installed in the secondary body shell, wherein the second port is configured such that the second port can fit together with the first port of the magnetic connector, and such that the second port and first port are held together in use by magnets.

19. A mounting bracket comprising a bracket body for fixing the vehicle-mounted electronic product of claim 3 in place, the bracket body having a second port of a magnetic connector, wherein the second port comprises a secondary body shell having magnets and several second signal pins installed in the secondary body shell, wherein the second port is configured such that the second port can fit together with the first port of the magnetic connector, and such that the second port and first port are held together in use by magnets.

20. A mounting bracket comprising a bracket body for fixing the vehicle-mounted electronic product of claim 4 in place, the bracket body having a second port of a magnetic connector, wherein the second port comprises a secondary body shell having magnets and several second signal pins installed in the secondary body shell, wherein the second port is configured such that the second port can fit together with the first port of the magnetic connector, and such that the second port and first port are held together in use by magnets.
